(19) United States
(12) Patent Application Publication
(10) Pub. No.: US 2007/0161301 A1
(43) Pub. Date: Jul. 12, 2007

(54) Multi-slave interface card reader

(75) Inventor: Ping-Yang Chuang, Taipei City (TW)

Correspondence Address: RABIN & Berdo, PC, 1101 14TH STREET, NW, SUITE 500, WASHINGTON, DC, 20005, US

(73) Assignees: A-DATA TECHNOLOGY CO., LTD., Taipei (TW); PING-YANG CHUANG, Taipei City (TW)

(21) Appl. No.: 11/649,910

(22) Filed: Jan. 5, 2007

(30) Foreign Application Priority Data
Jan. 6, 2006 (TW) 095200331

(51) Int. Cl. H05K 1/00

(52) U.S. Cl. 439/946

(57) ABSTRACT

A multi-slave interface card reader includes a card reader body having a USB signal interface plug and a 3C memory card interface receptacle installed on one side of the body being vertical to the USB signal interface plug for placing a memory card, e.g. Mini-SD, RS-MMC, Micro-SD, or Micro-MMC. Since the card reader body has the memory card installed therein, it is possible to place the card reader body in devices like cameras, MP3's, mobile phones . . . and so forth, to act as a memory. The USB signal interface plug can be directly connected to a computer host, or the card reader body can be connected to another card reader for transferring the data stored in the memory card to the computer through the card reader. Such a device of single body with multiple interfaces allows users to employ across various platforms, meanwhile also provides cost down benefits for manufacturers.

### BACKGROUND OF THE INVENTION

1. Field of the Invention

The present invention relates to an inventive improvement on memory card readers, with functionalities of card reading, signal conversions as well as data transmissions for different types of memory cards.

2. Description of Related Art

Card readers have currently become one of indispensable members for computer peripheral devices. Structures of general card readers are provided with a case, one side of which being installed a slot, while the other side a USB connector. In use of such structures, a memory card is made inserted into the slot, followed by connecting the USB connector to a USB slot on the computer. The card reader sends data stored in the memory card to the computer through the conversions in between, by the USB connector coupled to the computer.

However, as technologies advancing incessantly, vendors release new types of memory cards one after another, such as mini-SD announced by Panasonic, Toshiba from Japan, which provides a narrower volume than regular SD cards, facilitating applications on mobile phones or digital cameras. But most legacy card readers are not capable of reading such memory cards as the above-mentioned. Users are required to utilize a card adapter, into which one such memory card being plugged, then inserting this card adapter into the slot of card reader to perform reading function. Such processes are inconvenient for users; however, data in the memory cards can not be read without such adapters.

### SUMMARY OF THE INVENTION

Technical Issues Addressed

In view of such inconveniences caused by legacy card readers and memory cards, the present invention provides a design of card reader, in which internally installed a memory receptacle as well as yet a USB signal plug, such that the card reader of the present invention can directly send out the data in the memory card positioned inside the memory card receptacle; besides, because of the structural shape presented by the inventive card reader, it is possible to have the inventive card readers directly inserted into general 3C devices, e.g. cameras, mobile phones, MP3's, . . . , thus becoming adapters for different memory cards (adapters for memory cards with different sizes). Hence, the invention can become a card reader providing card reading and card conversion functionalities with more than 3 interfaces.

The present invention does not cause overloading of power consumption when being used with general 3C consumer devices, due to an automatic power management system therein.

Technical Means for Problem-Solving

To achieve the above-mentioned purposes, the present invention design a type of multi-slave interface card reader, whose technical approaches comprise as below:

Providing a card reading body, which has an appearance of a memory card, wherein such memory card can be of types SD, CF . . . etc. Such a card reader body includes a 3C memory card interface plug; a 3C memory card interface receptacle installed on one side being vertical to the 3C memory card interface plug; and a USB signal plug installed on the side opposing to the 3C memory card interface plug, in which an additional cover body is installed to match in closure with the USB plug. The accordingly designed card reader body can be positioned, along with the cover body, in devices like mobile phones, cameras . . . and so forth.

An alternative technical means is to install a 3C memory card interface slot on the horizontal plane of the card reader body, replacing the aforementioned 3C memory card interface receptacle, and to additionally install a moving cover matching the shape of the 3C memory card interface slot, in which one side of the moving cover is attached to the above-mentioned 3C memory card interface slot, whereas the other side provided for opening and closing.

The above-mentioned 3C memory card interface receptacle or 3C memory card interface slot is used for placing another memory card of smaller shape, in order to retransmit stored data, in which such a memory card with smaller shape can be Micro-SD, Mini-SD, RS-MMC or Micro-MMC . . . etc., and since the sizes of various memory cards differ, upon fabricating the 3C memory card interface receptacle or 3C memory card interface slot, it is possible to control the sizes in accordance with the memory cards required to be matched.

The aforementioned 3C memory card interface plug is provided with a form of general 3C consumer devices, such as SD cards, MMC cards, CF cards . . . etc, for plugging into 3C devices, e.g. cameras, mobile phones, MP3's, etc.

Effects on Prior Art

Compared with legacy memory cards/card readers, the inventive card reader can, seeing that a USB signal interface plug installed therein, be directly connected to a computer host, transmitting data stored in memory cards. Besides, the 3C memory card interface plug installed internally in the body is in the plug form of general 3C consumer devices, such as Mini-SD, Micro-SD, Micro-MMC memory cards . . . etc, hence the body of the inventive card reader can be positioned inside the devices such as cameras, MP3's, mobile phones . . . etc. as memories thereof. This technology of single body with multi-slave interfaces changes the feature of merely single slave interface in legacy memory cards/card readers, and shunts unstable connections of power supply and signal conflicts over multi-slave interfaces.

### BRIEF DESCRIPTION OF THE DRAWINGS

FIG. 1 shows a disengagement diagram for a preferred embodiment of the present invention;

FIGS. 2A and 2B show an assemblage diagram for a preferred embodiment of the present invention;

FIG. 3 shows a disengagement diagram for another embodiment of the present invention;

FIG. 4 shows the status of use for the present invention being connected to a computer host;

FIG. 5 shows the status of use for the present invention being connected to a card reader; and

FIG. 6 shows the status of use for the present invention being connected to a camera.

### DETAILED DESCRIPTION OF PREFERRED EMBODIMENTS

Now hereunder refer to appended drawings and component symbols for further detailed illustrations, enabling those who skilled in the art to implement the present invention when reading the specification document.

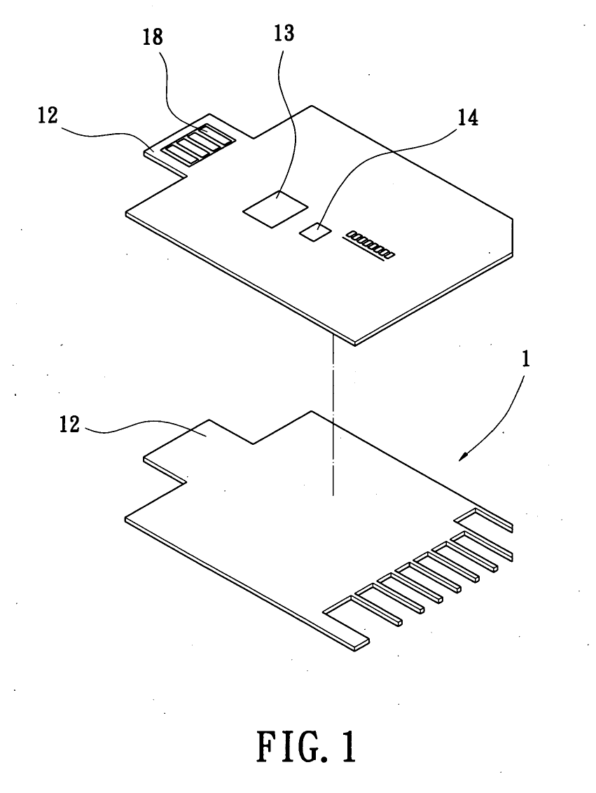

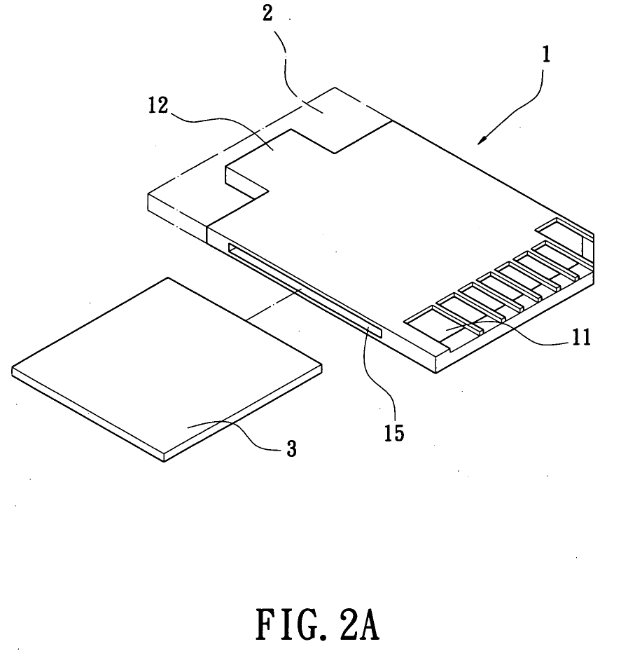

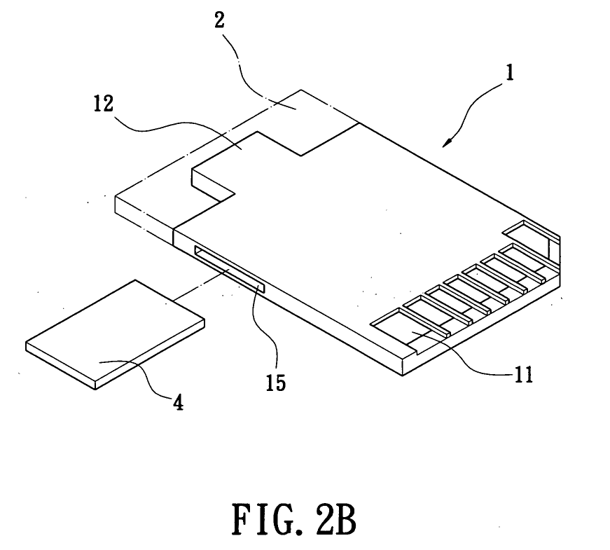

Referring now to FIG. 1, in which a disengagement diagram of a card reader 1 is shown. The card reader 1 has an appearance of memory card, which can be of type SD card, MMC card, CF card . . . and the like; thereon installed a circuit layout, mainly comprising a USB port 18 installed on the USB signal interface plug 12, a converter 13 and a buffer 14; additionally, a 3C memory card interface plug 11 is installed on the side at the back of the body, opposing to the USB signal port 18 (referring to FIG. 2).

Having the card reader body 1 assembled can achieve the appearance shown as FIGS. 2A and 2B. One implementation of the present invention is to install a 3C memory card interface receptacle 15 on one side being vertical to the 3C memory card interface plug 11, that the 3C memory card interface receptacle 15 extends to the body 1 inwardly, and the size of the 3C memory card interface receptacle 15 can be controlled during fabrication, allowing the 3C memory card interface receptacle 15 to be suitable for placing memory cards of size like Mini-SD 3, RS-MMC, or smaller memory cards such as Micro-SD 4, Micro-MMC . . . etc. Furthermore, a cover body 2 can be installed to connect and match in closure with the USB signal interface plug 12.

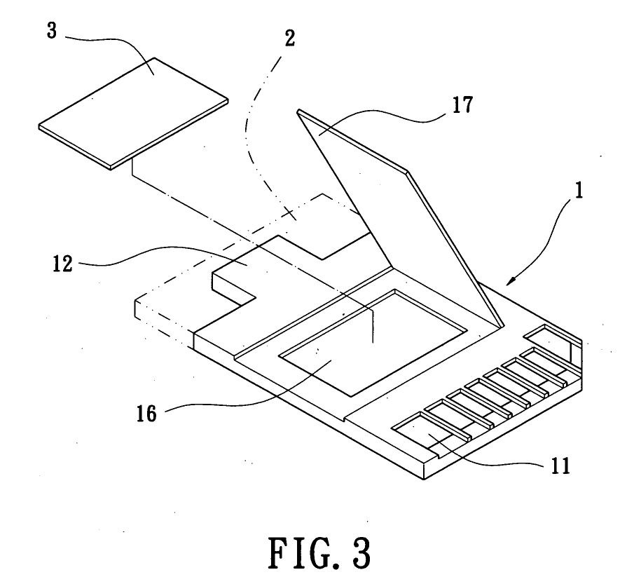

In terms of allocations of the memory card 3, 4, except such approach as the above-mentioned 3C memory card interface receptacle, there is also a possible way as illustrated in FIG. 3, in which a 3C memory card interface slot 16 having the memory card sizes relative to Mini-SD 3, RS-MMC . . . etc. or else to Micro-SD 4, Micro-MMC . . . etc., is installed on the horizontal plane side of the card reader body 1, thereon the 3C memory card interface plug 11 is configured, in order to accommodate the said memory cards; besides, a moving cover 17 of the shape relative to the 3C memory card interface slot 16 is installed, wherein one side of the moving cover 17 is connected to a side of the 3C memory card interface slot 16, while the other side allows the moving cover 17 to open and close.

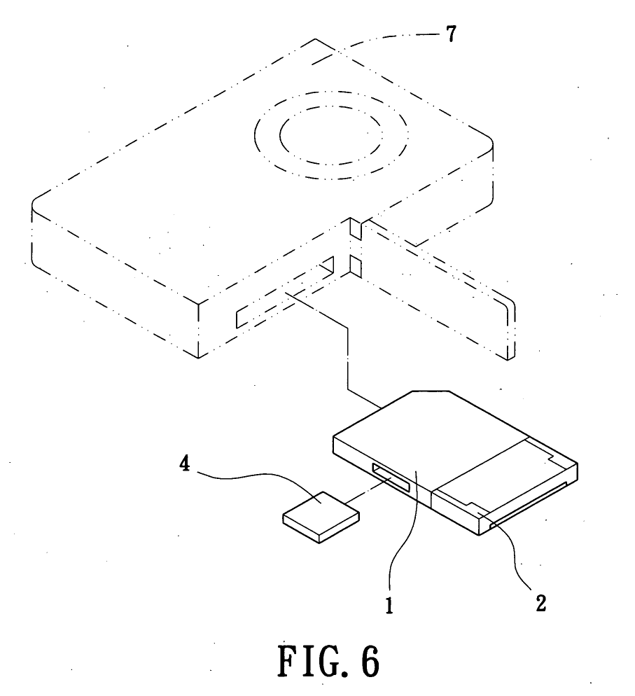

As shown in FIG. 6, since a memory card 4 is installed inside the inventive card reader body 1, it is possible to place the card reader body 1, along with the cover body 2, inside general 3C consumer devices like camera 7, MP3 . . . (not shown) to provide memory functionality. When it is required to transfer the data stored on the memory card located in the card reader body 1, the following approaches can be employed:

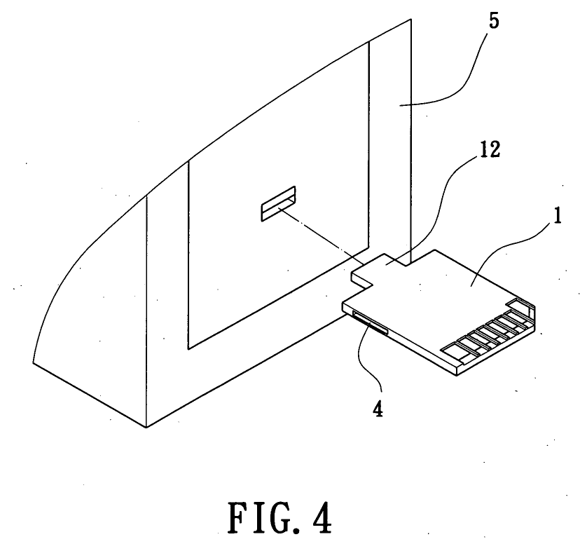

Referring to the diagram shown in FIG. 4, by means of the connection between the USB signal interface plug 12 on the card reader 1 and the computer host 5 (or other equipments offering the same USB interface), data stored on the memory card 4 can be transferred or accessed, demonstrating the functionality of plug-and-play.

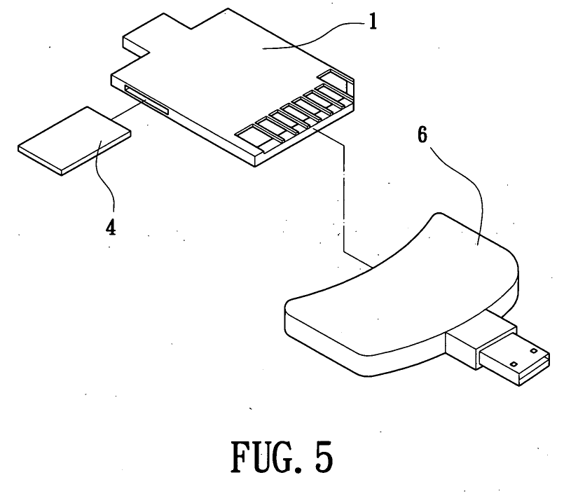

Referring again to FIG. 2A as well as FIG. 5, it is illustrated that a stick tab 19 (not shown) can be attached at the joint between the cover body 2 and the card reader body 1, such that the cover body 2 and the body 1 will not detach from each other. In this case, data in the memory card 4 is not transferred via the USB interface, but having the 3C memory card interface plug 11 of the card reader body 1 plugged into another card reader 6, then making the USB plug of the card reader 6 inserted into the USB receptacle on the computer for connection.

The aforementioned disclosure addresses merely to explain the preferred embodiments of the present invention, not intending to impose any restrictions in any forms over the present invention. Accordingly, all modifications or changes of the present invention performed under the same inventive spirits still fall within the scope intended to be encompassed by the present invention.

What is claimed is:

1. A multi-slave interface card reader, comprising:
a card reader body having a 3C memory card interface plug at one side thereof; a 3C memory card interface receptacle at another side vertical to the side the 3C memory card interface plug arranged; and a USB signal interface plug opposing to the 3C memory card interface plug, wherein the card reader body for installing inside a 3C device; and
a memory card, installed inside the 3C memory card interface receptacle for transferring and storing data.

2. The multi-slave interface card reader of claim 1, further comprising a cover body covered to the USB signal interface plug.

3. The multi-slave interface card reader of claim 2, wherein a stick tab is attached to a connection between the cover body and the card reader body.

4. The multi-slave interface card reader of claim 1, wherein the 3C memory card interface receptacle accommodates a Micro-SD memory card.

5. The multi-slave interface card reader of claim 1, wherein the 3C memory card interface receptacle accommodates a Mini-SD memory card.

6. The multi-slave interface card reader of claim 1, wherein the 3C memory card interface receptacle accommodates a RS-MMC memory card.

7. The multi-slave interface card reader of claim 1, wherein the 3C memory card interface receptacle accommodates a Micro-MMC memory card.

8. A multi-slave interface card reader, comprising:
a card reader body having a 3C memory card interface plug at one side thereof, the 3C memory card interface plug having a 3C memory card interface slot on a horizontal plane of the card reader body; a USD signal interface plug opposing to the 3C memory card interface plug; and a moving cover with a shape corresponding to the 3C memory card interface slot, the moving cover covered on the 3C memory card interface slot, wherein the card reader body for installing inside a 3C device;
a memory card, installed inside the 3C memory card interface slot for transferring and storing data.

9. The multi-slave interface card reader of claim 8, further comprising a cover body covered to the USB signal interface plug.

10. The multi-slave interface card reader of claim 9, wherein a stick tab is attached to a connection between the cover body and the card reader body.

11. The multi-slave interface card reader of claim 8, wherein the 3C memory card interface slot accommodates a Micro-SD memory card.

12. The multi-slave interface card reader of claim 8, wherein the 3C memory card interface slot accommodates a Mini-SD memory card.

13. The multi-slave interface card reader of claim 8, wherein the 3C memory card interface slot accommodates a RS-MMC memory card.

14. The multi-slave interface card reader of claim 8, wherein the 3C memory card interface slot accommodates a Micro-MMC memory card.
